(19) United States
(12) Patent Application Publication
(10) Pub. No.: US 2014/0233178 A1
(43) Pub. Date: Aug. 21, 2014

(54) Fan Impeller with Multiple Blades Shaped and Disposed to Provide High Air-Power Efficiency

(71) Applicant: John Franz, Houston, TX (US)

(72) Inventor: John Franz, Houston, TX (US)

(21) Appl. No.: 14/350,069

(22) PCT Filed: Oct. 28, 2011
(86) PCT No.: PCT/US2011/058373

§ 371 Date: Apr. 4, 2014

(51) Int. Cl. F04D 19/00; H05K 7/20

(52) U.S. Cl. CPC F04D 19/007; H05K 7/20136; H05K 7/20718
USPC 361/679.48; 416/198 R; 415/199.4; 361/695

(57) ABSTRACT

A fan impeller with multiple blades shaped and disposed to provide high air-power efficiency. The fan impeller includes a hub, a first plurality of primary blades and a second plurality of secondary blades. The leading edge of the first secondary blade is disposed proximately to the trailing edge of the first primary blade. A leading edge portion of the first secondary blade is also disposed in an inter-blade space between the first primary blade and a second primary blade. A trailing edge portion of the first secondary blade is disposed outside of the inter-blade space and towards a bottom of the hub. A cooling fan including the fan impeller, and an electrical apparatus including the cooling fan that includes the fan impeller are also provided.

### TECHNICAL HELD

Examples of the present technology relate generally to cooling technology for electronic apparatus, and more particularly to fan impellers for cooling fans used to cool an electronic apparatus.

### BACKGROUND

Cooling technology for electronic apparatus has gained increasing attention as electronics have become ever more complex. For example, the incorporation into electronic apparatus of high performance microprocessors has become almost ubiquitous. Such high performance microprocessors dissipate large amounts of heat due to their complex designs with ever increasing numbers of logic gates, and increasing speed. However, the performance of microprocessors and processors is very sensitive to the removal of the heat, which these devices generate. Thus, cooling technology has had to keep pace with, in particular, the increasing complexity of microprocessor and processor design and, more generally, the increasing complexity of electronic apparatus.

One area of on-going research and development that addresses the issue of heat removal from electronic apparatus is cooling-fan technology. To boost cooling efficiency, multiple cooling fans are often used to remove the heat generated by an electronic apparatus. However, such multi-fan solutions are costly due to the provision of two or more cooling fans, and the attendant supporting circuitry accompanying their operation. Thus, scientists and engineers engaged in the development of electronic-apparatus cooling technology are interested in developing new ways to address the issue of heat removal that are efficient, cost-effective, and reliable.

### DESCRIPTION OF THE DRAWINGS

The accompanying drawings, which are incorporated in and form a part of this specification, illustrate examples of the technology and, together with the description, serve to explain the examples of the technology:

FIG. 1A is a side perspective view of a fan impeller with multiple blades shaped and disposed to provide high air-power efficiency, in accordance with examples of the present technology.

FIG. 1B is a side perspective view of the fan impeller of FIG. 1A, illustrating various dimensions of the fan impeller pertinent to providing high air-power efficiency, in accordance with examples of the present technology.

FIG. 2 is a side perspective view of an alternative example of a fan impeller with multiple blades shaped and disposed to provide high air-power efficiency, in accordance with examples of the present technology.

FIG. 3 is a drawing of plots of fan-impeller air-flow and air-power efficiency showing the effects of fan impellers having secondary blades, in accordance with examples of the present technology, as compared with fan impellers without secondary blades.

FIG. 4 is a plan view of a cooling fan including the fan impeller of FIG. 1, in accordance with examples of the present technology.

FIG. 5 is a schematic diagram showing an electrical apparatus including the cooling fan of FIG. 4 that includes the fan impeller of FIG. 1, in accordance with examples of the present technology.

The drawings referred to in this description should not be understood as being drawn to scale except if specifically noted.

### DESCRIPTION OF EXAMPLES

Reference will now be made in detail to the alternative examples of the present technology. While the technology will be described in conjunction with the alternative examples, it will be understood that they are not intended to limit the technology to these examples. On the contrary, the technology is intended to cover alternatives, modifications and equivalents, which may be included within the spirit and scope of the technology as defined by the appended claims.

Furthermore, in the following description of examples of the present technology, numerous specific details are set forth in order to provide a thorough understanding of the present technology. However, it should be noted that examples of the present technology may be practiced without these specific details. In other instances, well known methods, procedures, and components have not been described in detail as not to unnecessarily obscure examples of the present technology. Throughout the drawings, like components are denoted by like reference numerals, and repetitive descriptions are omitted for clarity of explanation if not necessary. As used herein, the articles, “a” and “an,” will also be understood as including the plural referents. Also, as used herein, the articles, “the” and “said,” will also be understood as including the plural referents.

Examples of the present technology include a fan impeller with multiple blades shaped and disposed to provide high air-power efficiency. The fan impeller includes a hub, a first plurality of primary blades and a second plurality of secondary blades. A first primary blade of the first plurality has a first shape, and includes a leading edge and a trailing edge. Similarly, a first secondary blade of the second plurality has a second shape, and includes a leading edge and a trailing edge. The first primary blade is disposed closer to a top of the hub than the first secondary blade. The leading edge of the first secondary blade is disposed proximately to the trailing edge of the first primary blade. A leading edge portion of the first secondary blade is also disposed in an inter-blade space between the first primary blade and a second primary blade. A trailing edge portion of the first secondary blade is disposed outside of the inter-blade space and towards a bottom of the hub. Examples of the present technology also include a cooling fan including the fan impeller, and an electrical apparatus including the cooling fan that includes the fan impeller.

Examples of the present technology address the issue that creating a single blade shape that can obtain a high level of air-power efficiency simultaneously with high air-flow and high air pressure is a daunting task, because the blade parameters for each performance goal, viz., high air-flow, and high air pressure, leads to divergent designs. Examples of the present technology use two different blade shapes such that each blade shape is designed to meet different performance goals, but when combined the two different blade shapes produce an unexpected synergy that achieves a unique performance result.

Examples of the present technology address the issue that the traditional practice of using only one blade shape leads to adjustments that alter performance at the cost of some negative side effect. For example, to increase flow you can increase the blade camber, or angle of attack; but, increasing the blade camber, or angle of attack, leads to efficiency losses and increases the dip in the stall. Alternatively, if a designer wants more pressure and efficiency, it comes at the expense of air-flow volume.

Examples of the present technology utilize two unique blade shapes attached to the same hub. In accordance with examples of the present technology, a primary blade has a “longer” shape biased axially to the inlet of the cooling fan; and, a secondary blade has a “shorter” shape biased towards the rear of the fan impeller close to trailing edge of the primary blade. The spacing between the primary blade and the secondary blade depends on many factors; but, in one example of the present technology, the spacing between a primary blade and a secondary blade is uniformly constant along the circumference of the hub, which is useful in obtaining high through-put volume in an injection molding process used to fabricate fan impellers. In accordance with examples of the present technology, the primary blade shape is larger having a longer chord length and small angle of attack. The primary blade generates the pressure performance and is highly air-flow efficient. The secondary blade shape is smaller, and has a shorter camber and larger angle of attack. The secondary blade provides the flow volume capability, but is less efficient. The high angle of attack of the secondary blade would increase the chance of stall, if the secondary blade were part of a typical cooling fan with blades having just one blade shape. However, in accordance with examples of the present technology, the flow separation is reduced because of the upstream primary blade trailing edge that has altered the air flow pattern, In accordance with examples of the present technology, the result is a cooling fan capable of producing high pressure, which is characteristic of a cooling fan with blades having a low angle of attack, but with more overall air-flow volume, which is characteristic of a cooling fan with blades having a high angle of attack, without loss of air-power efficiency,

Thus, examples of the present technology are useful, because the cooling fan having a fan impeller with a primary blade and a secondary blade of two different shapes is capable of providing higher flow without increasing cooling fan size or speed, when compared with cooling fans having fan impellers with blades of just one shape. Moreover, examples of the present technology find utility from the ability to hard-tool fabrication processes for the fan impeller, such as injection molding, because the secondary blades are short, pose less complexity in fabricating injection-mold dies, and are less susceptible to “locking up” in the die in an injection molding process that may be used to manufacture the fan impeller. In addition, examples of the present technology provide cooling fans including a fan impeller that can maintain air-power efficiency, compared with normal methods of achieving equivalent cooling-fan performance that may result in lower air-power efficiency. Furthermore, examples of the present technology provide cooling fans that consume less fan power, at equal performance, compared to cooling fans having fan impellers with blades of a single shape.

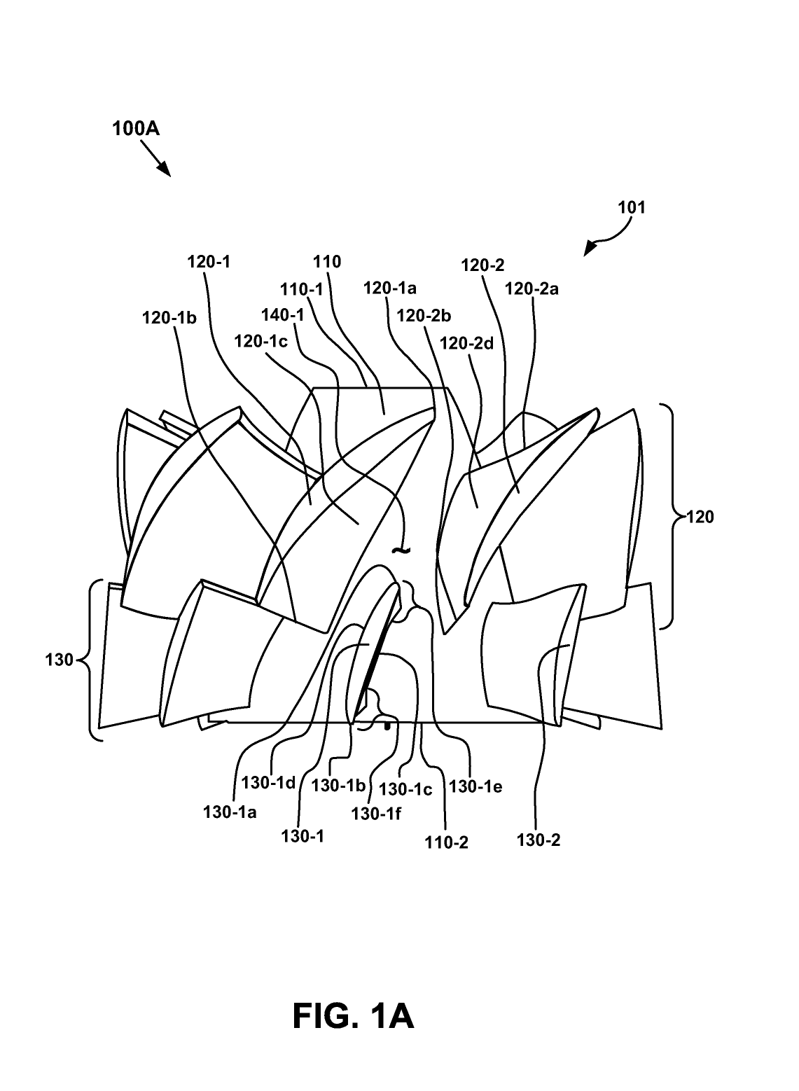

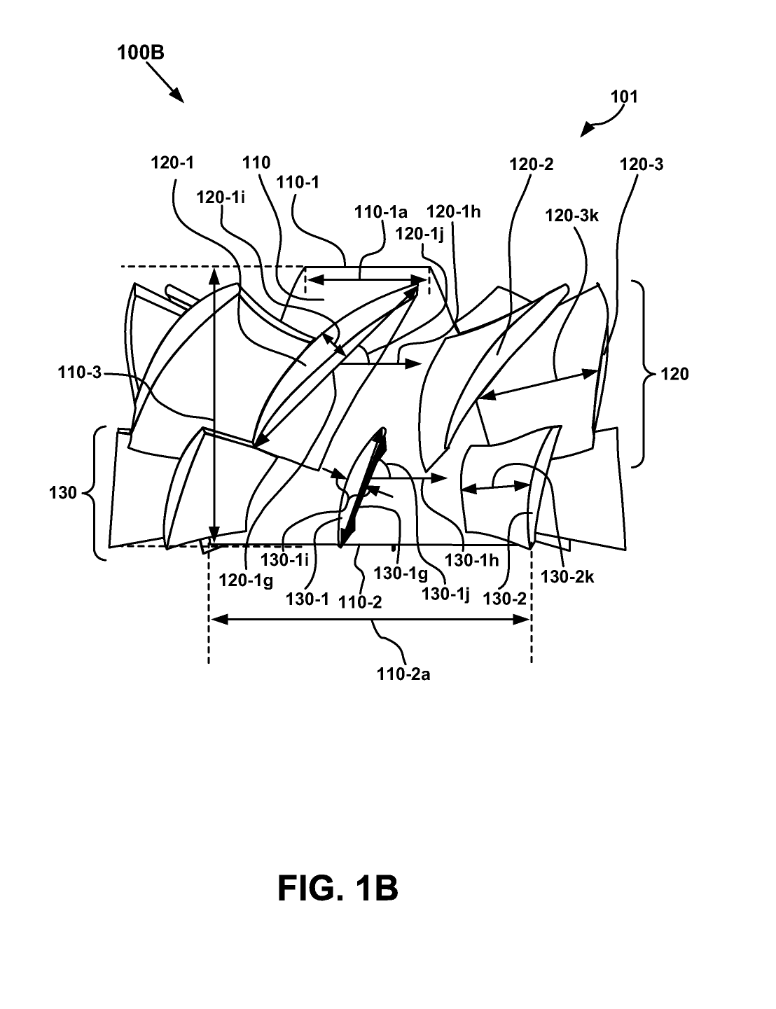

With reference now to FIG. 1A, in accordance with examples of the present technology, a side perspective view 100A is shown of a fan impeller 101 with multiple blades shaped and disposed to provide high air-power efficiency. The fan impeller 101 includes a hub 110, a first plurality 120 of primary blades, for example, primary blades 120-1 and 120-2, and a second plurality 130 of secondary blades, for example, secondary blades 130-1 and 130-2. As shown in FIG. 1A, by way of example., the fan impeller 101 has about eight primary blades and about eight secondary blades, without limitation thereto, as examples of the present technology include fan impellers with fewer or more primary and secondary blades than that shown. The first primary blade 120-1 of the first plurality 120 includes a leading edge 120-1a, and a trailing edge 120-1b, as do other primary blades; for example, second primary blade 120-2 also includes a leading edge 120-2a, and a trailing edge 120-2b, The first primary blade 120-1 of the first plurality 120 also includes a high pressure surface 120-1c disposed at the bottom side of the first primary blade 120-1, and a low pressure surface (hidden from view in FIG. 1A) disposed at the top side of the first primary blade 120-1, as do other primary blades; for example, second primary blade 120-2 also includes a high pressure surface (hidden from view in FIG. 1A) disposed at the bottom side of the second primary blade 120-2, and a low pressure surface 120-2d disposed at the top side of the second primary blade 120-2. The first primary blade. 120-1 is disposed closer to a top 110-1 of the hub 110 than the first secondary blade 130-1, which is next described in greater detail.

With further reference to FIG. 1A, in accordance with examples of the present technology, the first secondary blade 130-1 of the second plurality 130 includes a leading edge 130-1a, and a trailing edge 130-1b, as do other secondary blades; for example, second primary blade 130-2 also includes a leading edge (unlabeled), and a trailing edge (unlabeled). As described herein, not all of the aerodynamic surfaces of various component parts of the fan impeller 101 are labeled so as not to unnecessarily clutter the figures. The first secondary blade 130-1 of the second plurality 130 also includes a high pressure surface 130-1c disposed at the bottom side of the first secondary blade 130-1, and a low pressure surface 130-1d disposed at the top side of the first secondary blade 130-1, as do other secondary blades; for example, second secondary blade 130-2 also includes a high pressure surface (unlabeled) disposed at the bottom side of the second secondary blade 130-2, and a low pressure surface (unlabeled) disposed at the top side of the second secondary blade 130-2. The first secondary blade 130-1 includes a leading edge portion 130-1e and a trailing edge portion 130-1f, the arrangement of which is next described

With further reference to FIG. 1A, in accordance with examples of the present technology, the leading edge 130-1 a of the first secondary blade is disposed proximately to the trailing edge 120-1 b of the first primary blade 120-1. A leading edge portion 130-1e of the first secondary blade 130-1 is also disposed in an inter-blade space 140-1 between the first primary blade 120-1 and a second primary blade 120-2. A trailing edge portion 130-1f of the first secondary blade 130-1 is disposed outside of the inter-blade space 140-1 and towards a bottom 110-2 of the hub 110. As shown in FIG. 1A, by way of example without limitation thereto, the leading edge portion 130-1 e of the first secondary blade 130-1 is disposed in the inter-blade space 140-1 midway between the first primary blade 120-1 and a second primary blade 120-2. The impeller 101 including the hub 110, the first plurality 120 of primary blades and the second plurality 130 of secondary blades may be one single unitary body. In accordance with examples of the present technology, the single unitary body is without separable subcomponents, and is without coupling means for coupling subcomponents. Such coupling means include those selected from the group consisting of fasteners, interlocking structures, and bonding agents. Examples of fasteners include screws, pins, and rivets, without limitation thereto. Examples of interlocking structures include keys, key ways, splines, and dove-tail joints, without limitation thereto. Examples of bonding agents include glue, adhesives, adhesive tape, fusible plastic beads, and solvents used to fuse separate plastic components together, without limitation thereto. Thus, in one example of the present technology, the fan impeller 101 is suitable for low-cost fabrication in an injection molding process.

With reference now to FIG. 1B, in accordance with examples of the present technology, a side perspective view 100B is shown of the fan impeller of FIG. 1A. FIG. 1B illustrates various dimensions of the fan impeller 101 pertinent to providing high air-power efficiency. The first primary blade 120-1 of the first plurality 120 of primary blades is shaped as a first airfoil; and, the first secondary blade 130-1 of the second plurality 130 of secondary blades is shaped as second airfoil. Thus, the first primary blade 120-1 has a chord length 120-1g, an upper camber 120-1i, an angle of attack 120-1j, and a blade length (unlabeled), for example, similar to the blade length 120-3k of third primary blade 120-3, which is more discernible than that of first primary blade 120-1 in FIG. 1B. Similarly, the first secondary blade 130-1 has a chord length 130-1g, an upper camber 130-1i, an angle of attack 130-1j, and a blade length (unlabeled), for example, similar to the blade length 130-2k of second secondary blade. 130-2, which is more discernible than that of first secondary blade 130-1 in FIG. 1B. In accordance with examples of the present technology, the chord length 130-1g of the first secondary blade 130-1 is less than the chord length 120-1g of the first primary blade 120-1. In one example of the present technology, the chord length 130-1g of the first secondary blade 130-1 is about a third of the chord length 120-1g of the first primary blade 120-1. Moreover, in one example of the present technology, the blade length (unlabeled) of the first secondary blade 130-1 is less than the blade length (unlabeled) of the first primary blade 120-1. Due to the perspective of FIG. 1B, the relative sizes of the first secondary blade 130-1 and the first primary blade 120-1 may be better understood by comparing the blade length 130-2k of the second secondary blade 130-2 to the blade length 120-3k of the third primary blade 120-3, which are about the same as the blade lengths of the first secondary blade 130-1 and the first primary blade 120-1, respectively. Thus, in accordance with examples of the present technology, the first primary blade 120-1 of the first plurality 120 of primary blades has a first shape. Similarly, in accordance with examples of the present technology, the first secondary blade 130-1 of the second plurality 130 of secondary blades has a second shape, that may differ from the first shape of the first primary blade 120-1 of the first plurality 120 of primary blades.

With further reference to FIG. 1B, in accordance with examples of the present technology, the angle of attack 120-1j of the first primary blade 120-1 is defined by the angle between the chord length 120-1g of the first primary blade 120-1 and the direction of motion 120-1h of the first primary blade 120-1, when the hub 110 rotates. Similarly, the angle of attack 130-1j of the first secondary blade 130-1 is defined by the angle between the chord length 130-1g of the first secondary blade 130-1 and the direction of motion 130-1h of the first secondary blade 130-1, when the hub 110 rotates. In accordance with examples of the present technology, the angle of attack 120-1j of the first primary blade 120-1 is less than the angle of attack 130-1j of the first secondary blade 130-1. Moreover, in one example of the present technology, as the chord length 120-1g and the blade length of the first primary blade 120-1 are, respectively, greater than the chord length 130-1g and the blade length of the first secondary blade 130-1, the blade area of the first primary blade 120-1 may be greater than the blade area of the first secondary blade 130-1.

With further reference to FIG. 1B, in accordance with examples of the present technology, the hub 110 may have a tapered shape. Thus, as shown in FIG. 1B, a top diameter 110-1a of the hub 110 at the top 110-1 of the hub 110 is less than a bottom diameter 110-2a of the hub 110 at the bottom 110-2 of the hub 110. In one example of the present technology, the top diameter 110-1a of the hub 110 may be about 8 millimeters (mm); and, the bottom diameter 110-2a of the hub 110 may be about 25 mm. Also, the height 110-3 of the hub 110 may be about 28 mm. Thus, in one example of the present technology, the tapered shape of the hub 110 may provide for increased air pressure generated at the outlet of the cooling fan.

In addition, although the fan impeller 101 has been described in terms of specific individual primary blades and secondary blades, this is by way of example and not limitation thereto, as primary blades may have similar shapes and dimensions to one another; and, similarly, secondary blades may have similar shapes and dimensions to one another. Moreover, the preceding discussion of the overall shapes and dispositions of the blades of the fan impeller 101 is by way of example without limitation thereto, as other overall shapes and dispositions of the blades of the fan impeller 101 with respect to one another are also within the spirit and scope of examples of the present technology and may differ from those shown in FIGS. 1A and 1B, an example of which is next described.

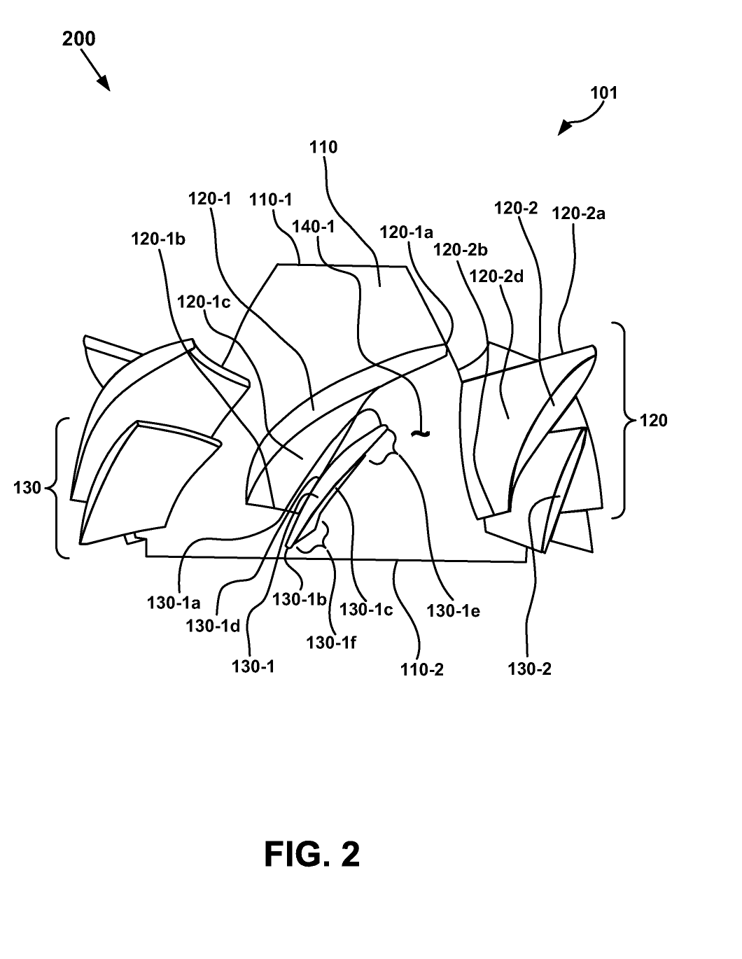

With reference now to FIG. 2, in accordance with examples of the present technology, a side perspective view 200 is shown of an alternative example of the fan impeller 101 with multiple blades shaped and disposed to provide high air-power efficiency. Similar to FIGS. 1A and 1B, the fan impeller 101 includes a hub 110, a first plurality 120 of primary blades, for example, primary blades 120-1 and 120-2, and a second plurality 130 of secondary blades, for example, secondary blades 130-1 and 130-2. However, as shown in FIG. 2, by way of example, the fan impeller 101 has about six primary blades and about six secondary blades, without limitation thereto. The first primary blade 120-1 of the first plurality 120 includes a leading edge 120-1a, and a trailing edge 120-1b, as do other primary blades; for example, second primary blade 120-2 also includes a leading edge 120-2a, and a trailing edge 120-2b. The first primary blade 120-1 of the first plurality 120 also includes a high pressure surface 120-1c disposed at the bottom side of the first primary blade 120-1, and a low pressure surface (hidden from view in FIG. 2) disposed at the top side of the first primary blade 120-1, as do other primary blades; for example, second primary blade. 120-2 also includes a high pressure surface (hidden from view in FIG. 2) disposed at the bottom side of the second primary blade 120-2, and a low pressure surface 120-2d disposed at the top side of the second primary blade 120-2. The first primary blade 120-1 is disposed closer to a top 110-1 of the hub 110 than the first secondary blade 130-1. Examples of the present technology also include within their spirit and scope a fan impeller 101, where the relative positions of a first primary blade 120-1 and a first secondary blade 130-1 are shifted up or down along the vertical axis of the hub 110, and/or are shifted circumferentially around the vertical axis of the hub from those shown in FIGS. 1A-2. For example, the first primary blade 120-1 may be positioned closer to the top 110-1 of the hub 110 than shown in FIGS. 1A-2; the first secondary blade 130-1 may be positioned closer to the bottom 110-2 of the hub 110 than shown in FIGS. 1A-2; and, the relative spacing between the first primary blade 120-1 and the first secondary blade 130-1 may be closer, or alternatively farther apart, than shown in FIGS. 1A-2.

With further reference to FIG. 2, in accordance with examples of the present technology, the first secondary blade 130-1 of the second plurality 130 includes a leading edge 130-1a, and a trailing edge 130-1b, as do other secondary blades; for example, second primary blade 130-2 also includes a leading edge (unlabeled), and a trailing edge (unlabeled). The first secondary blade 130-1 of the second plurality 130 also includes a high pressure surface 130-1c disposed at the bottom side of the first secondary blade 130-1, and a low pressure surface 130-1d disposed at the top side of the first secondary blade 130-1, as do other secondary blades; for example, second secondary blade 130-2 also includes a high pressure surface (unlabeled) disposed at the bottom side of the second secondary blade 130-2, and a low pressure surface (unlabeled) disposed at the top side of the second secondary blade 130-2. The first secondary blade 130-1 includes a leading edge portion 130-1e and a trailing edge portion 130-1f, the arrangement of which is next described.

With further reference to FIG. 2, in accordance with examples of the present technology, the leading edge 130-1a of the first secondary blade is disposed proximately to the trailing edge 120-1b of the first primary blade 120-1. A leading edge portion 130-1e of the first secondary blade 130-1 is also disposed in an inter-blade space 140-1 between the first primary blade 120-1 and a second primary blade 120-2. A trailing edge portion 130-1f of the first secondary blade 130-1 is disposed outside of the inter-blade space 140-1 and towards a bottom 110-2 of the hub 110. However, as shown in FIG. 2 in contrast with FIGS. 1A and 1B, the leading edge portion 130-1e of the first secondary bade 130-1 is disposed in the inter-blade space 140-1 closer to a high pressure surface 120-1c of the first primary blade 120-1 than to a low pressure surface 120-2d of the second primary blade 120-2. Also, the overall shapes of the first primary blade 120-1 and the first secondary blade 130-1 differ from the respective shapes shown in FIGS. 1A and 1B. In particular, the angle of attack of the first primary blade 120-1 shown in FIG. 2 Is greater than the angle of attack of the first primary blade 120-1 shown in FIGS. 1A and 1B. Moreover, the chord length of the first secondary blade 130-1 shown in PG. 2 is greater than the chord length of the first secondary blade 130-1 shown in FIG. 1A and 1B. Thus, by way of example without limitation thereto, FIG. 2 demonstrates some of the range of design variations that are within the spirit and scope of examples of the present technology.

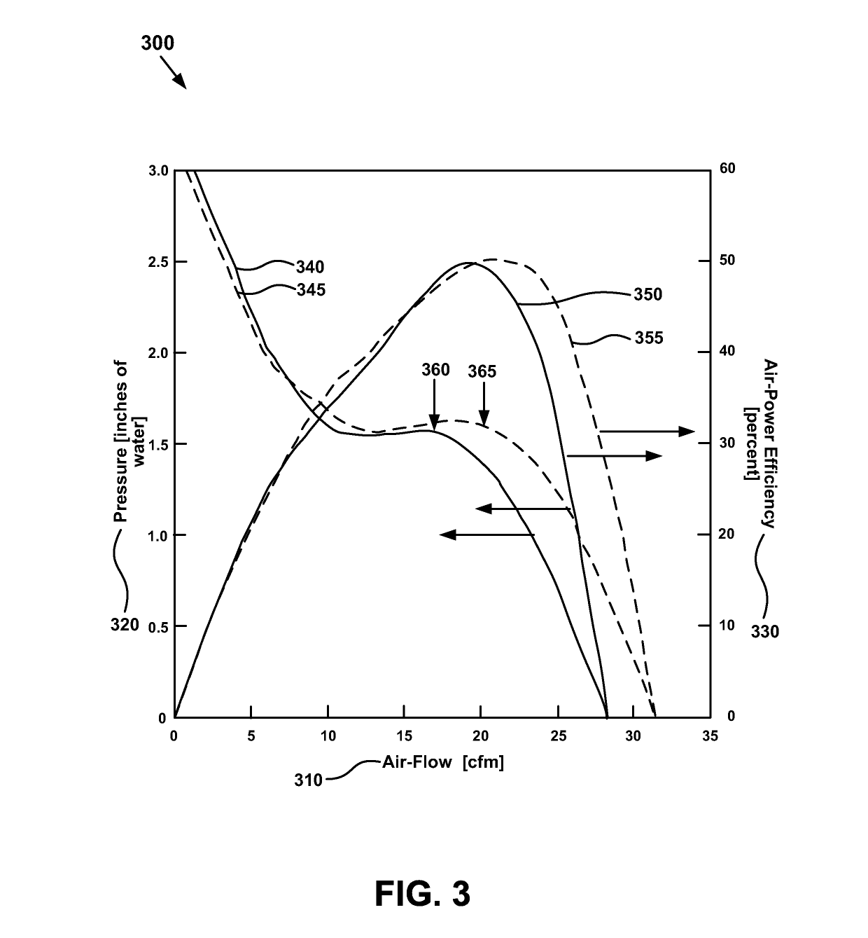

With reference now to FIG. 3, a drawing 300 is shown of plots of fan-impeller air-flow curves 340 and 345 and air-power efficiency curves 350 and 355. FIG. 3 shows the effects of the fan impeller 101 including a second plurality 130 of secondary blades, for example, secondary blades 130-1 and 130-2, in accordance with examples of the present technology, as compared with a fan impeller without the second plurality 130 of secondary blades. The data shown in FIG. 3 is for cooling fans with three primary blades and a hub spinning at about 22×10³ revolutions per minute (krpm). Although data shown in FIG. 3 is for cooling fans of a combined three primary blade and three secondary blade design, and a three primary blade design without secondary blades, the data is representative of the performance of a fan impeller 101 similar to the designs shown in FIGS. 1A-2 compared to a fan impeller without secondary blades, respectively. The solid curves 340 and 350 correspond to a cooling fan with primary blades, but without secondary blades. The dashed curves 345 and 355 correspond to a cooling fan with both primary blades and secondary blades. The abscissa 310 in FIG. 3 is air-flow in units of cubic feet per minute (cfm). The left-hand-side ordinate 320 in FIG. 3 is pressure generated at the outlet of the respective cooling fans in units of inches of water. The air-flow curves 340 and 345, or “fan curves,” of the respective cooling fans refer to the left-hand-side ordinate 320 in FIG. 3, as indicated by the left-pointing arrows. The right-hand-side ordinate 330 in FIG. 3 is air-power efficiency of the respective cooling fans in units of percent. The air-power efficiency curves 350 and 355 of the respective cooling fans refer to the right-hand-side ordinate 330 in FIG. 3 as indicated by the right-pointing arrows. Air-power efficiency, also referred to as “aerodynamic efficiency,” was calculated from the respective fan curves given by the following formula: air-power efficiency=(air-flow power/motor efficiency)/fan input power, where motor efficiency is given by the formula: motor efficiency=(motor torque×motor rotary speed)/motor input power. The air-flow power was calculated from the fan curves by taking the product of the abscissa and ordinate of points along the fan curves; thus, air-flow power is given by the following formula: air-flow power (watts)=(air-flow×pressure)/8.515. The conversion factor 8.515 takes into account the density of air and conversion of various units of the parameters in the formula for air-power efficiency.

With further reference to FIG. 3, inspection of the air-flow curve 345 for the combined three primary blade and three secondary blade design with the air-flow curve 340 for the three primary blade design without secondary blades shows the “knees” in the air-flow curves associated with stall points of the respective fan impellers. For examples of the present technology, the first secondary blade 130-1 is disposed to increase a stall point 365 of the fan impeller 101 to a point of higher air-flow than a stall point 360 of a fan impeller without the second plurality 130 of secondary blades, of which first secondary blade 130-1 and second secondary blade 130-2 are examples. Moreover, as shown in FIG. 3, in accordance with examples of the present technology, the air-power efficiency 355 of the fan impeller 101 is about equal to or greater than an air-power efficiency 350 of a fan impeller without the second plurality 130 of secondary blades, of which first secondary blade 130-1 and second secondary blade 130-2 are examples.

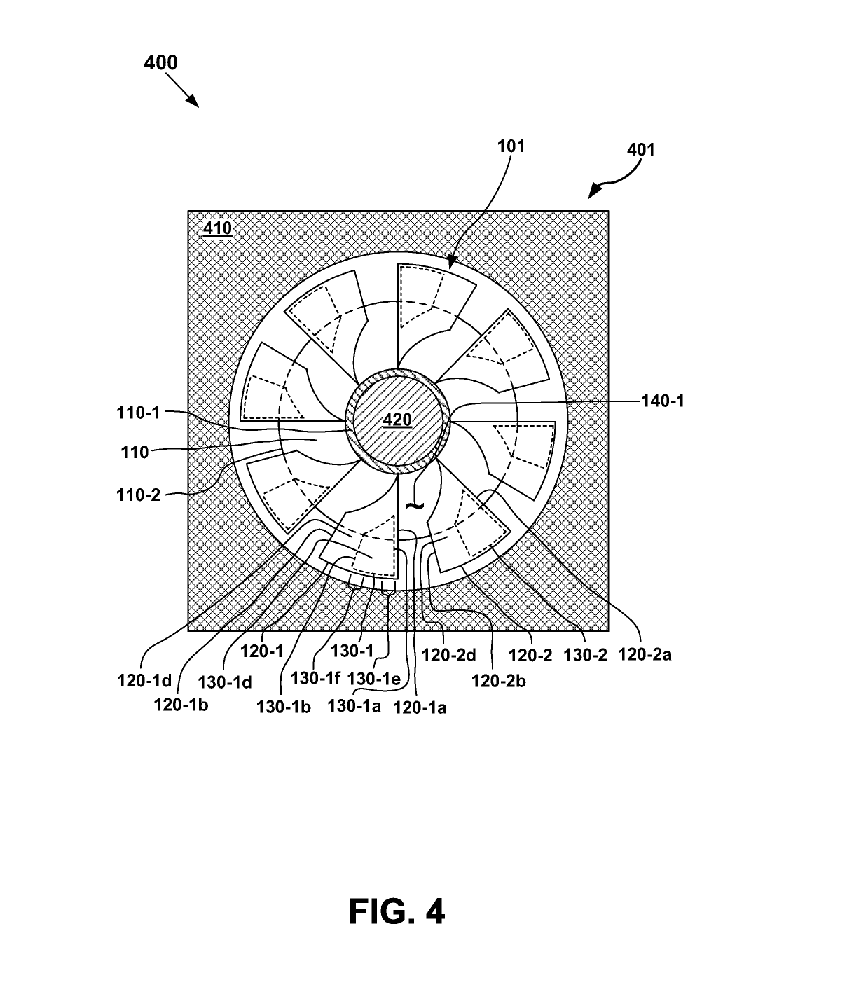

With reference now to FIG. 4 and further reference to FIGS. 1A-2, in accordance with examples of the present technology, a plan view 400 is shown of a cooling fan 401 including the fan impeller 101 of FIG. 1. The plan view 400 shown in FIG. 4 is orthogonal to the perspective views 100A, 100B and 200 shown in FIGS. 1A-2, The cooling fan 401 includes a fan impeller 101 with multiple blades shaped and disposed to provide high air-power efficiency. In accordance with examples of the present technology, the cooling fan 401 includes a stator 410, a rotor 420 rotatably mounted in the stator 410, and a fan impeller 101 coupled to the rotor 420. FIG. 4 shows the appearance of the cooling fan 401 and the fan impeller 101 as viewed down the axis of the rotor 420 of the cooling fan 401. Examples of the present technology previously described in the discussion of FIGS. 1A-2 for the fan impeller 101 are incorporated within the environment of the cooling fan 401, some of which are next described.

Thus, with further reference to FIG. 4, in accordance with examples of the present technology, the fan impeller 101 includes a hub 110, a first plurality 120 of primary blades, of which first primary blade 120-1 and second primary blade 120-2 are examples, and a second plurality 130 of secondary blades, of which first secondary blade 130-1 and second secondary blade 130-2 are examples. A first primary blade 120-1 of the first plurality 120 has a first shape, and includes a leading edge 120-1a, a trailing edge 120-1b, a high pressure surface 120-1c (not shown in FIG. 4, but see FIGS. 1A-2), and a low pressure surface 120-1d. Also shown in FIG. 4, the second primary blade 120-2 of the first plurality 120 also has about the same first shape as the first primary blade 120-1, which is characteristic of primary blades of the plurality 120 of primary blades, and includes a leading edge 120-2a, a trailing edge 120-2b, a high pressure surface 120-1c (not shown in FIG. 4, but see FIGS. 1A-2), and a low pressure surface 120-1d. Similarly, a first secondary blade 130-1 of the second plurality 130 has a second shape, and includes a leading edge 130-1a, a trailing edge 130-1b, a high pressure surface 130-1c (not shown in FIG. 4, but see FIGS. 1A-2), and a low pressure surface 130-1d. As shown in FIG. 4, the second secondary blade 130-2 of the second plurality 130 also has about the same second shape as the second secondary blade 130-1, which is characteristic of secondary blades of the plurality 130 of secondary blades. The first primary blade 120-1 is disposed closer to a top 110-1 of the hub 110 than the first secondary blade 130-1. Although not apparent from the view of FIG. 4 due to loss of perspective along the axial direction of the cooling fan 401 lying along the axis of the rotor 420, which is perpendicular to the plane of FIG. 4, the leading edge 130-1a of the first secondary blade is disposed proximately to the trailing edge 120-1b of the first primary blade 120-1. A leading edge portion 130-1e of the first secondary blade 130-1 is also disposed in an inter-blade space 140-1 between the first primary blade 120-1 and a second primary blade 120-2. A trailing edge portion 130-1f of the first secondary blade 130-1 is disposed outside of the inter-blade space 140-1 and towards a bottom 110-2 of the hub 110.

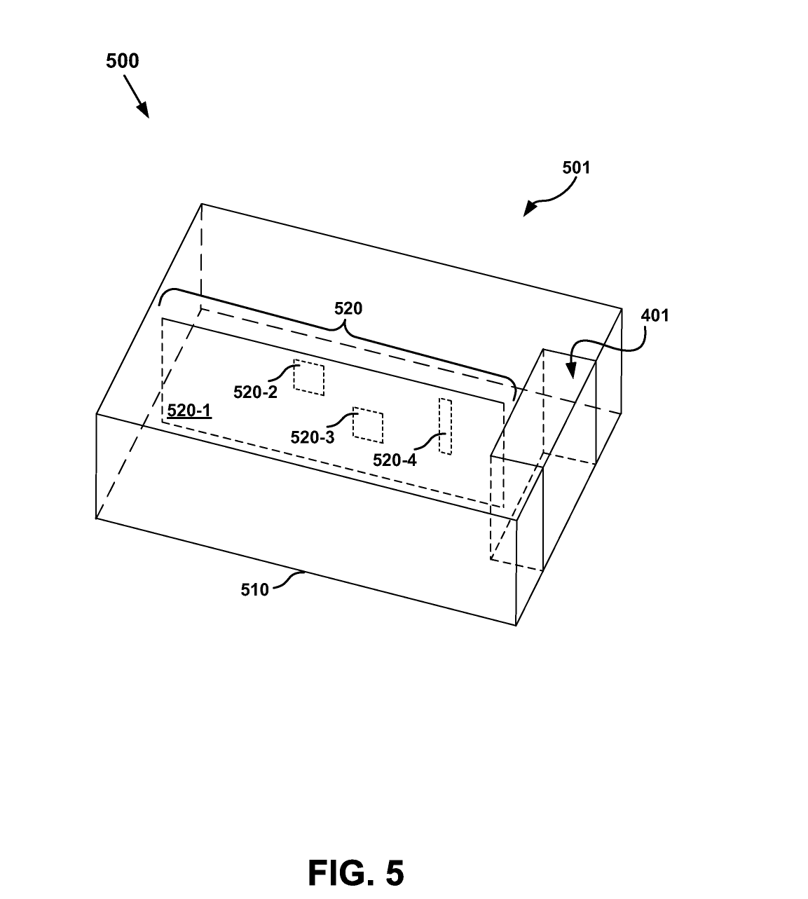

With reference now to FIG. 5 and further reference to FIGS. 1A-2 and 4, in accordance with other examples of the present technology, a schematic diagram 500 is shown of an electrical apparatus 501 including the cooling fan 401 of FIG. 4 that includes the fan impeller 101 of FIG. 1. The electrical apparatus 501 has a cooling fan 401 for cooling that has a fan impeller 101 with multiple blades shaped and disposed to provide high air-power efficiency. In accordance with examples of the present technology, the electrical apparatus includes a chassis 510, a plurality 520 of electrical components 520-1, 520-2, 520-3, 520-4 disposed in the chassis 510, and a cooling fan 401 mounted in the chassis 510 to cool the plurality 520 of electrical components 520-1, 520-2, 520-3, 520-4. By way of example, the electrical components may be selected from the group consisting of a printed circuit board PCB 520-1, a microprocessor 520-1, a video processor 520-3, and a memory module 520-4, without limitation thereto.

With further reference to FIG. 5 and FIGS. 1A-2 and 4, examples of the present technology previously described in the discussion of FIG. 4 for the cooling fan 401 are included within the environment of the electrical apparatus 501. The cooling fan 401 includes a stator 410, a rotor 420 rotatably mounted in the stator 410, and a fan impeller 101 coupled to the rotor 420. Examples of the present technology previously described in the discussion of FIGS. 1A-2 for the fan impeller 101 are also included within the environment of the electrical apparatus 501, some of which are next described. The fan impeller 101 includes a hub 110, a first plurality 120 of primary blades, of which first primary blade 120-1 and second primary blade 120-2 are examples, and a second plurality 130 of secondary blades, of which first secondary blade 130-1 and second secondary blade 130-2 are examples, A first primary blade 120-1 of the first plurality 120 has a first shape, and includes a leading edge 120-1a, and a trailing edge 120-1b. Similarly, a first secondary blade 130-1 of the second plurality 130 has a second shape, and includes a leading edge 130-1a, and a trailing edge 130-1b. The first primary blade 120-1 is disposed closer to a top 110-1 of the hub 110 than the first secondary blade 130-1. The leading edge 130-1a of the first secondary blade is disposed proximately to the trailing edge 120-1b of the first primary blade 120-1. A leading edge portion 130-1e of the first secondary blade 130-1 is also disposed in an inter-blade space 140-1 between the first primary blade 120-1 and a second primary blade 120-2. A trailing edge portion 130-1f of the first secondary blade 130-1 is disposed outside of the inter-blade space 140-1 and towards a bottom 110-2 of the hub 110.

With further reference to FIG. 5, in accordance with other examples of the present technology, by way of example, the electrical apparatus 501 may be selected from the group consisting of a computer, a disk-drive array, and a network switching apparatus, without limitation thereto. The network switching apparatus may also be selected from the group consisting of switches and routers. Moreover, in another example of the present technology, the electrical apparatus 501 may further include a blade server.

The foregoing descriptions of specific examples of the present technology have been presented for purposes of illustration and description. They are not intended to be exhaustive or to limit the technology to the precise forms disclosed, and many modifications and variations are possible in light of the above teaching. The examples described herein were chosen and described in order to best explain the principles of the technology and its practical application, to thereby enable others skilled in the art to best utilize the technology and various examples with various modifications as are suited to the particular use contemplated. It may be intended that the scope of the technology be defined by the claims appended hereto and their equivalents.

What is claimed is:

1. A fan impeller with multiple blades shaped and disposed to provide high air-power efficiency, said fan impeller comprising:
a hub;
a first plurality of primary blades coupled to said hub;
a second plurality of secondary blades coupled to said hub; and
wherein a first primary blade is disposed closer to a top of said hub than a first secondary blade, a leading edge of said first secondary blade is disposed proximately to a trailing edge of said first primary blade, a leading edge portion of said first secondary blade is disposed in an inter-blade space between said first primary blade and a second primary blade, and a trailing edge portion of said first secondary blade is disposed outside of said inter-blade space and towards a bottom of said hub.

2. The fan impeller of claim 1, wherein said leading edge portion of said first secondary blade is disposed in said inter-blade space midway between said first primary blade and a second primary blade.

3. The fan impeller of claim 1, wherein said leading edge portion of said first secondary bade is disposed in said inter-blade space closer to a high pressure surface of said first primary blade than to a low pressure surface of said second primary blade.

4. The fan impeller of claim 1, wherein said first secondary blade is disposed to increase a stall point of said fan impeller to a point of higher air-flow than a stall point of a fan impeller without said second plurality of secondary blades.

5. The fan impeller of claim 1, wherein said air-power efficiency of said impeller is about equal to or greater than an air-power efficiency of an impeller without said second plurality of secondary blades.

6. The fan impeller of claim 1, wherein said first primary blade and said first secondary blade are shaped as airfoils.

7. The fan impeller of claim 1, wherein a chord length of said first secondary blade is less than a chord length of said first primary blade.

8. The fan impeller of claim 7, wherein said chord length of said first secondary blade is about a third of said chord length of said first primary blade.

9. The fan impeller of claim 1, wherein said hub has a tapered shape, and a top diameter of said hub is less than a bottom diameter of said hub.

10. The fan impeller of claim 1, wherein said impeller including said hub, said first plurality of primary blades and said second plurality of secondary blades further comprises one single unitary body.

11. The fan impeller of claim 10, wherein said single unitary body is without separable subcomponents, and is without a coupling means for coupling subcomponents, said coupling means selected from the group consisting of fasteners, interlocking structures, and bonding agents.

12. A cooling fan having a fan impeller with multiple blades shaped and disposed to provide high air-power efficiency, said cooling fan comprising:
a stator;
a rotor rotatably mounted in said stator; and
a fan impeller coupled to said rotor, said fan impeller comprising:
a hub;
a first plurality of primary blades coupled to said hub;
a second plurality of secondary blades coupled to said hub; and
wherein a first primary blade is disposed closer to a top of said hub than a first secondary blade, a leading edge of said first secondary blade is disposed proximately to a trailing edge of said first primary blade, a leading edge portion of said first secondary blade is disposed in an inter-blade space between said first primary blade and a second primary blade, and a trailing edge portion of said first secondary blade is disposed outside of said inter-blade space and towards a bottom of said hub.

13. An electrical apparatus having a cooling fan for cooling and having a fan impeller with multiple blades shaped and disposed to provide high air-power efficiency, said electrical apparatus comprising:
a chassis;
a plurality of electrical components disposed in said chassis; and
a cooling fan mounted in said chassis to cool said plurality of electrical components, said cooling fan comprising:
a stator;
a rotor rotatably mounted in said stator; and
a fan impeller coupled to said rotor, said fan impeller comprising:
a hub;
a first plurality of primary blades coupled to said hub;
a second plurality of secondary blades coupled to said hub; and
wherein a first primary blade is disposed closer to a top of said hub than a first secondary blade, a leading edge of said first secondary blade is disposed proximately to a trailing edge of said first primary blade, a leading edge portion of said first secondary blade is disposed in an inter-blade space between said first primary blade and a second primary blade, and a trailing edge portion of said first secondary blade is disposed outside of said inter-blade space and towards a bottom of said hub.

14. The electrical apparatus of claim 13, wherein said electrical apparatus is selected from the group consisting of a computer, a disk-drive array, and a network switching apparatus.

15. The electrical apparatus of claim 13, wherein said electrical apparatus further comprises s a blade server.
